(19) United States
(12) Patent Application Publication
(10) Pub. No.: US 2013/0034969 A1
(43) Pub. Date: Feb. 7, 2013

(54) Thin Film Deposition Method

(71) Applicant: Lingkuan Meng, Beijing (CN)

(72) Inventor: Lingkuan Meng, Beijing (CN)

(21) Appl. No.: 13/504,962

(22) PCT Filed: Jan. 10, 2012
(86) PCT No.: PCT/CN2012/000037

§ 371 Date: Apr. 30, 2012

(30) Foreign Application Priority Data
Jul. 14, 2011 (CN) 201110197889.3

(51) Int. Cl. H01L 21/314

(52) U.S. Cl. 438/761; 257/E21.266

(57) ABSTRACT

The present invention provides a thin film deposition method, comprising: seasoning a first deposition chamber; seasoning a second deposition chamber; pre-processing the first deposition chamber, depositing a thin film in the first deposition chamber, cleaning the first deposition chamber, post-processing and withdrawing the wafers; pre-processing the second deposition chamber, depositing a thin film in the second deposition chamber, cleaning the second deposition chamber, post-processing and withdrawing the wafers; characterized in that there is a time interval between the step of seasoning the second deposition chamber and the step of seasoning the first deposition chamber. The method of stabilizing the thin film thickness of the present invention can well solve the problem that the thin film on the first pair of wafers of each batch of products becomes thinner or thicker during the deposition. In addition, the present invention greatly reduces the influences from human activities without increasing the seasoning wafers, thus realizing automation; moreover, the affected wafers no longer need to be scraped, thus increasing the yield of products.

### CROSS REFERENCE

This application is a National Stage Application of, and claims priority to, PCT Application No. PCT/CN2012/000037, filed on Jan. 10, 2012, entitled “Thin Film Deposition Method”, which claims priority to Chinese Application No. 201110197889.3, filed on Jul. 14, 2011. Both the PCT application and the Chinese application are incorporated herein by reference in their entireties.

### FIELD OF THE INVENTION

The present invention relates to a thin film deposition method, in particular to a method for depositing a thin film with a stable thickness.

### BACKGROUND OF THE INVENTION

In ULSI (Ultra Large Scale Integration) device manufacturing, with the continuous reduction in chip CD (Critical Dimension), for example, to 0.18 μm or smaller, delay, interference and power consumption resulted from interconnect parasitic resistance and capacitance have become a bottleneck problem in the development of multifunctional integrated circuits with high speed, high-density and low power consumption. As interconnect and the number of the layers for the interconnect increase rapidly, the line width of the metal interconnect is reduced and integration becomes higher. This in turn results in an increase in Resistance and Capacitance (RC) Time Delay caused by the resistance and capacitance in the conductor interconnection system. Operating speed of the circuit is adversely influenced. In order to reduce the signal delay time in the interconnection system, materials of low dielectric constant (low-k) (k<3.0) have been widely used in Inter-Metal-Dielectric (IMD) to replace the conventional silicon dioxide (k=3.9) thin film so as to reduce the delay in capacitance, for technology node of 0.18 μm or smaller. Instead of Al, Cu is used as the material of interconnect metal wires, and Damascus, electroplating and the like are used to fill copper into trenches.

The low-k material used for ULSI should not only have a dielectric constant as low as possible, but it should also have good thermal stability, high mechanical strength and reliability. Meanwhile it should be easily patterned and etched, be compatible with Chemical Mechanical Polishing process and be adapted to the complexity of integration in the ULSI backend. Generally, the material used for dielectric includes mainly silicon dioxide (SiO₂) made by Plasma Enhanced Chemical Vapor Deposition (PECVD), with a dielectric constant of 3.9. For deep sub-micron node, while scaling down the device, materials with low dielectric constant are required to achieve the expected performance, such as reduced signal delay, reduced power loss and reduced interference between signals.

Now, various low-k materials which have been developed are widely used in manufacturing semiconductor integrated circuits, for example, such as Black Diamond (Silicon Oxycarbide, SiOC, BD for short), also called organic silicate glass. BD is a low dielectric constant material, available from Applied Materials, deposited by PECVD with low polarity molecules such as methyl and oxygen doped into silicon dioxide which is the basis.

In Plasma Enhanced Chemical Vapor Deposition (PECVD), plasma, which is formed by ionization under the excitation of external radio frequency electric field, causes the precursor(s) containing the components of a thin film to react chemically in order to grow the thin film. A characteristic that distinguishes PECVD from other CVD methods is that the plasma in PECVD contains a large amount of high-energy electrons, which provide activation energy required in Chemical Vapor Deposition, unlike the general CVD which requires a supply of high energy to enable the reaction. The collision of electrons and vapor molecules can prompt decomposition, combination, excitation and ionization of gas molecules so as to generate various highly active chemical groups. Thus, the temperature at which CVD thin film is deposited can be remarkably low, so that the CVD process that can otherwise be performed only at high temperature can be performed now at low temperature.

At present, in manufacturing integrated circuits of 12 inches, i.e. 300 millimeters, especially starting from the 90 nanometer technology node, BD material has been widely used in copper interconnection as a dielectric isolation layer. Therefore, its stability in thickness is very important for the subsequent double Damascus etching, copper metal layer filling and the final copper CMP. Particularly, keeping the thickness for different wafers and different batches and the uniformity thereof will lay a good foundation for the processes to be carrying out. In large-scale manufacturing, if a wafer becomes thinner or thicker in a certain process, the next process will face a great challenge and the wafer is probably to be discarded. This results in a great cost loss.

For multi-hole low-k dielectric thin films, such as BD, a frequently occurring problem is the effect that the thickness of the first pair of wafers of every lot of products becomes thinner. For example, if the thickness is 6000 Å, a deviation of 500 Å will occur due to the inappropriate process. Thus, in subsequent double Damascus etching, the barrier layer as an underlayer may be over etched, which will result in reliability problems such as VBD (Voltage Break Down).

Apparently, the thickness of the dielectric thin film made by PECVD relates to many factors, such as the major deposition parameters, including chamber pressure, gas flow rate, chamber temperature and deposition time. Besides, an overlong idling of the chamber and an inappropriate seasoning process will also cause the thickness to deviate from the normal value. However, instead of the chamber deposition parameters which are relatively stable, change of the chamber deposition condition possibly is a reason for large vary of the thickness. As far as PECVD is concerned, before wafers of every lot are transported to the chamber and a thin film is deposited on them, a seasoning process will be carried out inside the process chamber. In the seasoning process, any thin film that has been deposited in the chamber is removed to reduce the risk that wafers are polluted by particles and the chamber is passivated, i.e. depositing a layer of thin film in the chamber. This helps to make the chamber to be in an environment the same as or similar to that for a normal deposition, preventing the adverse thickness change effect of the wafers on which deposition is performed subsequently and particle pollution, which are caused by the overlong idling of the chamber owing to, for example, tool preventative maintenance or other issues. Normally, for a conventional dielectric thin film, such as silicon dioxide, silicon nitride, silicon oxynitride and fluorosilicate glass, even if the chamber has been idling for a long time, after carrying out a seasoning process, the first pair of wafers will not be influenced too much by the effect of the thickness change, i.e. thinner or thicker.

A deposition apparatus having two chambers and two load-ports is taken as an example, such as the PECVD system available from Applied Materials company. There are two common reasons for chamber idling. Since there is only one buffer chamber which determines whether wafers can be transported into the deposition chambers or not, the deposition chambers will be waiting for a very long time after the seasoning process. This is the first influence factor. With respect to a two-chamber or multi-chamber system, in a mode of serial sequence deposition, if a first batch of wafers only use one of the chambers, the other chamber will be in an idling state. When the following lot need to be deposited in both chambers, said two chambers will both undergo the seasoning process, including cleaning and passivating. However, upon the completion of the seasoning process, if the wafers of first lot are still in the first chamber, the second chamber will be in an idling and waiting state for a long time. This is another typical influence factor. If a chamber stays idling for a long time, the chamber deposition rate will drop greatly, and the thickness of the thin film will be reduced accordingly. FIG. 1 is a schematic drawing showing a comparison of the deposition rates of the low-k BD thin film when the chamber is idle or not idle. Apparently, the longer the idle time is, the lower the deposition rate is. Accordingly, the thickness of deposition drops rapidly. This explains why the thickness of the first pair of wafers reduces with the increase of the idling time.

Therefore, the key for solving the problem that the first pair of wafers become thinner is to reduce the waiting time before depositing on the wafers, so that the step of depositing on the wafers can be performed directly after the seasoning process.

A conventional method of solving this problem includes depositing directly on the next lot without leaving any idle time for the chamber or increasing the frequency of seasoning. But this has a strict requirement on the timing of transporting. Furthermore, it wastes human resources and can hardly realize manufacture automation, so the productivity is greatly reduced. In any way, with respect to the low-k (Black Diamond, BD) thin film deposited by PECVD, there is a problem that the first pair of wafers become thinner, because the deposition rate is considerably reduced compared with that of normal wafers. The problem brings about fatal influences on the subsequent dielectric etching, copper electroplating and CMP, and causes problems in device reliability.

### SUMMARY OF THE INVENTION

In view of the problem of the effect that the first pair become thinner in the low-k thin film deposited by the PECVD method, the present invention provides an effective method for stabilizing and controlling the thin film thickness.

The present invention provides a thin film deposition method, comprising: seasoning first deposition chamber; seasoning second deposition chamber; depositing a thin film in the first chamber and cleaning the first chamber; depositing a thin film in the second chamber and cleaning the second chamber; characterized in that there is a certain time interval between the seasoning the second deposition chamber and the seasoning the first deposition chamber.

In the present invention, said time interval is a difference of a total time from transporting from a load-port to the end of deposition and cleaning between the first chamber and the second chamber.

In the present invention said time interval may also be any other proper time interval selected according to specific process steps or execution processes of the wafers, as long as the second deposition chamber does not have any idle time that affects the thickness.

In the present invention the first and/or second chambers are PECVD chambers.

In the present invention there is also a step of seasoning the third deposition chamber, and the time interval between the seasoning the third chamber and the seasoning the first chamber is equal or not equal to the time interval between the seasoning second chamber and the seasoning first chamber.

The present invention also provides a method of manufacturing a semiconductor device, comprising: depositing an etching barrier layer on a semiconductor structure; depositing a dielectric insulating layer on the etching barrier layer using the previously described thin film deposition method; and depositing a cover layer on the dielectric insulating layer.

In the present invention the etching barrier layer includes SiN or NDC or N-Blok (Nitrogen Doped Carbide) or other dielectric materials that can be used for the barrier layer.

In the present invention the dielectric insulating layer includes a material of low dielectric constant. Said material of low dielectric constant includes fluorosilicone glass (FSG), BD or SiOC (Carbon Doped Oxide) or other carbon-doped materials of low dielectric constant. Wherein, said SiOC is made by using OMCTS or TMCTS or other carbon-based precursors.

In the present invention the cover layer includes undoped SiO₂ or doped SiO₂. Wherein, the cover layer is made by using TEOS, SiH4 or precursors containing the corresponding doping elements.

In the present invention the deposition is performed by using PECVD.

The method of stabilizing the thin film thickness according to the present invention can be applied to both low-k materials and other thin film materials to well solve the problem that the thin film on the first pair of wafers of each batch of products becomes thinner or thicker during the deposition process. In addition, the method of stabilizing and controlling the thin film thickness according to the present invention greatly reduces the influences from human activities without increasing the seasoning wafers, thus realizing automation; most importantly, the affected wafers no longer need to be scraped, thus increasing the yield of products.

Said object of the present invention and other objects not described herein are achieved within the scope described in the independent claims of this application. The embodiments of the present invention are defined in the independent claims and the specific features thereof are defined in the dependent claims.

### BRIEF DESCRIPTION OF THE DRAWINGS

The technical solution of the present invention will be described in detail below with reference to the drawings.

FIG. 1 is a schematic drawing of the variation of deposition rate of the low-k BD thin film with time when the chamber is idle or not idle;

FIG. 2 is a dielectric thin film sandwich structure for use in a backend copper interconnection;

FIG. 3 is a schematic drawing of the flow of a conventional PECVD seasoning process;

FIG. 4 is a schematic drawing of the flow of a time sharing PECVD seasoning process of the present invention; and

FIG. 5 is a schematic drawing of the flow of another time sharing PECVD seasoning process of the present invention.

### DETAILED DESCRIPTION OF THE PREFERRED EMBODIMENTS

The features and technical effects of the technical solution of the present invention are described in detail below with reference to the drawings and in conjunction with the exemplary embodiments, and a method of stabilizing and controlling the thin film thickness is disclosed. It shall be noted that similar reference signs denote similar structures, and the terms “first”, “second”, “on”, “under” and the like used in this application can be used to modify various device structures or process steps. Such modification does not intend to imply the spatial, sequential or hierarchical relations between the device structures or process steps being modified unless it is specifically indicated so.

FIG. 2 shows a sandwich structure, wherein a low-k thin film is deposited by PECVD on a semiconductor structure on which a backend copper process has been performed. The backend copper process begins upon the basic semiconductor CMOS structure 1 is formed. According to the standard process, a etching barrier layer 2, which is a low-k dielectric thin film including silicon nitride (SiN) or N-doped silicon carbide (NDC) or N-BLOK, is first deposited on the basic structure 1 using a PECVD process as a etching stop layer in the subsequent Damascus process. Then a low-k dielectric thin film is deposited on the etching barrier layer 2 by PECVD, as a dielectric insulating layer 3 between metal wires and between metal of the same layer, including a low-k dielectric material such as F-doped SiO₂, i.e. fluorosilicone glass (FSG), SiOC, or Black Diamond. SiOC may be made by using octamethylcyclotetrasiloxane (OMCTS), tetramethylcyclotetrasiloxane (TMCTS) or other carbonaceous precursors. Next, a cover layer 4 is deposited according to process requirements, which is made of un-doped SiO₂ or doped SiO₂. For example, it can be made by using TEOS, SiH₄ or the precursors containing the corresponding doping elements. The cover layer can block vapor and impurities and improve the uniformity of the thickness. The three layers are a very typical IMD interconnection sandwich structure, as shown in FIG. 2. The PECVD low-k BD dielectric thin film of Applied Materials has been commercialized for many years, the deposition parameters and preparation conditions thereof have come to perfection, so they will not be further described any more in the present invention. As for the dielectric thin film(s) to be used, it can be chosen according to the process nodes and the need of the manufacturers, while the present invention will not make specific limitation. The present invention is focused on providing a method solving the problem that the thickness of the first pair of thin films deviates from the target value regardless of the type of the thin film prepared by PECVD, so the materials and ways of deposition of the etching barrier layer 2, the dielectric insulating layer 3 and the capping layer 4 are not limited to the specific limitations given above, but they should include all suitable dielectric materials and deposition processes.

The present invention is described by taking the preparation of the low-k BD dielectric thin film of the middle layer as shown in the sandwich structure of FIG. 2, as an example. The most commonly used tools with two load-ports and two chambers, i.e. chamber A and chamber B, is considered. When both of the two chambers are in an idle state, a lot is placed therein. Since the two chambers have been idling for a long time, a seasoning process will be performed.

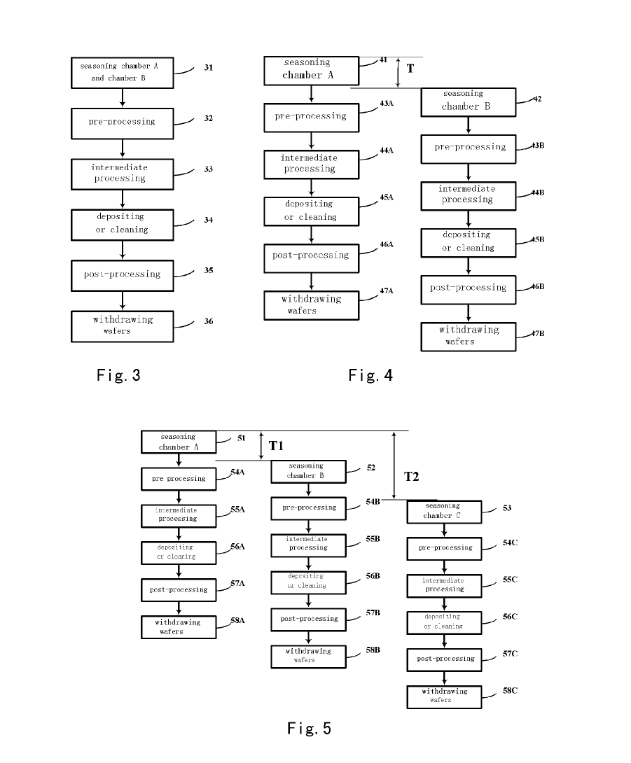

A conventional seasoning procedure, as shown in the flow chart of FIG. 3, is as follows: at step 31, seasoning chamber A and chamber B, namely, a seasoning process is performed for chamber A and chamber B simultaneously; at step 32, performing pre-processing, including vacuumizing the chambers, feeding rare gases into the chambers, pre-drying and/or pre-cleaning, etc. so as to stabilizing the chamber condition; at step 33 performing intermediate processing, for example, a pre-reaction step such as feeding reaction gases and turning on the radio frequency power; at step 34 performing depositing or cleaning, i.e. deposing a thin film in the chambers and cleaning the chambers after deposition; at step 35 performing post-processing, such as turning off the radio frequency power and the reaction gases; at step 36 withdrawing the wafers. According to the sequence, the seasoning process of step 31 is performed in chambers A and B substantially at the same time. The time for the seasoning mainly depends on cleaning and passivation and varies with the specific process. However, in a serial deposition process, the wafers will first are placed into the first chamber, meanwhile the second chamber is in a state of waiting for receiving wafers, because the buffer chamber can only send wafers into one deposition chamber once. As a result, the second chamber will be idling for a very long time. Accordingly, the following deposition rate will be reduced and the thickness of the first pair wafers will be affected. Finally, the deposition rate of the first pair wafers becomes lower and the thickness thereof becomes thinner and deviates from the target value.

### First Embodiment

In view of the abovementioned, a time division step added to address this situation according to the present invention. As long as the time needed by the buffer chamber and the time needed for seasoning or cleaning the second chamber are calculated correctly, the second chamber no longer has to be in a waiting state for a long time. Thus, the deposition rate for wafers will not be affected by the idling time. The thin film(s) of the first pair wafers is prevented from becoming thinner and reliability of devices and the yield of products are improved according to the present invention.

The flow chart of the seasoning process of the present invention is shown in FIG. 4. Specifically, the present invention starts from step 41, at which chamber A is seasoned, i.e. the seasoning process starts from chamber A. Any thin film that has been deposited in the chamber is removed to reduce the risk that particles pollute the subsequent wafers. Then the chamber is passivated by depositing a layer of thin film in the chamber.

Next, at step 42, chamber B is seasoned. Step 42 is performed after step 41 with a delay of a time interval T. The time difference T is a difference of the total time from transporting wafers off the corresponding load-port to the completion of the deposition and cleaning between the first chamber and the second chamber, namely, the difference between the total time of transporting wafers from the corresponding load-port to the second chamber B, depositing and cleaning the second chamber B and the total time of transporting wafers from the corresponding load-port to the first chamber A, depositing and cleaning the first chamber A. In addition, the time difference T may also be any other appropriate time interval selected according to a specific process step or wafer execution process, as long as it ensures that the chamber B does not have any necessary idling, or in other words, as long as it can ensure that a first pair of wafers do not become thinner in chamber B. For example, if other steps are added into steps 43 to 47, then the time interval T will be added the time consumed by the added steps.

Then, the pre-processing of step 43, the intermediate processing of step 44, the depositing or cleaning of step 45, the post-processing of step 46, and the withdrawing wafers of step 47 are performed sequentially. Steps 43 to 47 are sequentially performed according to the current state of the respective chamber, as shown in FIG. 4, that is, including the steps performed respectively in chambers A and B. Step A means that it is performed in chamber A, and step B means that it is performed in chamber B. In other words, the pre-processing step for chamber A does not have to be started until the completion of the stabilizing step for chamber B, i.e. there can be overlapping of time for the two steps as long as the stabilizing step for chamber A has been completed.

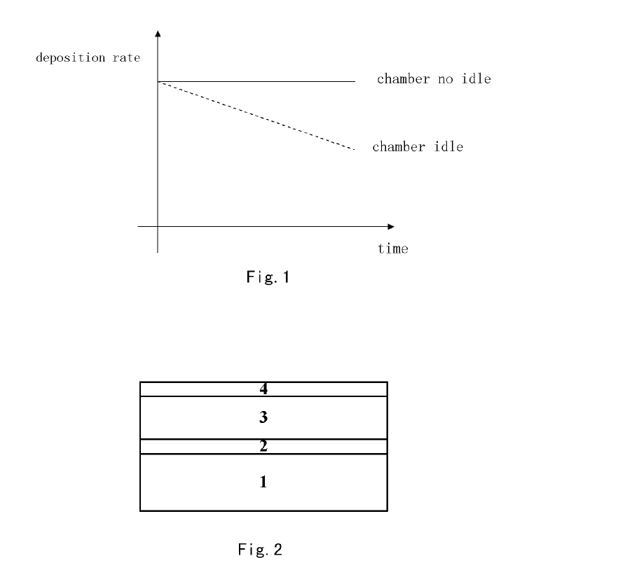

Tests show that the deposition rate of the first pair has been stabilized at a normal level, as shown by the deposition rate curve in a non-idling state in FIG. 1.

Thus, a time difference in transporting wafers from the load-port to the chamber and cleaning the chamber after deposition is considered, which is denoted by T (second). With respect to the seasoning process executed for chamber A, the execution in chamber B is delayed by T seconds so as to avoid the problem that would occur during execution of the conventional seasoning menu. In this case, the idle time for chamber B can be reduced to the minimum.

### Second Embodiment

The first embodiment is described with respect to a double-chamber deposition system, but in addition to this, a multiple-chamber (e.g. three chambers, four chambers or more chambers) deposition system adopted in the industry can also use the thin film thickness controlling method of the present invention.

Specifically, reference can be made to FIG. 5.

First, at step 51, the first chamber is stabilized, i.e. the seasoning process starts from the first chamber.

Second, after step 51, with a delay of a first time interval T1 seconds, the second chamber is stabilized at step 52. T1 depends on the time difference in transporting wafers from the load-port to the chamber and cleaning the chamber after deposition, namely, it is a time difference of transporting, depositing and cleaning wafers between the second chamber and the first chamber.

Next, after step 51, with a delay of a second time interval T2 seconds, the third chamber is stabilized at step 53. T2 is a time difference of transporting, depositing and cleaning wafers between the third chamber and the first chamber. T2 may be the same as or different from T1, depending on specific needs of chamber seasoning processing.

Subsequently, the pre-processing of step 54, the intermediate processing of step 55, the depositing or cleaning of step 56, the post-processing of step 57 and the withdrawing wafers of step 58 are performed sequentially. Similar to the first embodiment, the second embodiment uses steps A, B and C to indicate the processing steps performed respectively in the three different chambers.

Likewise, a thin film thickness controlling method for a deposition system with four chambers or more chambers can be obtained by deduction and modification on the basis of the second embodiment.

The method of stabilizing the thin film thickness according to the present invention can be applied to both low-k materials and other thin film materials to well solve the problem that the thin film(s) on the first pair of wafers of each batch of products becomes thinner or thicker. In addition, the method of stabilizing and controlling the thin film thickness according to the present invention greatly reduces the influences from human activities without seasoning wafers additionally, thus realizing automation; most importantly, the affected wafers no longer need to be discarded, thus increasing the yield of products.

While the invention has been described in conjunction with one or more exemplary embodiments, those skilled in the art shall understand that many appropriate variations and equivalent substitutions can be made to the process flow without departing from the scope of the present invention. Moreover, many modifications that might be suitable for specific conditions or materials can be made from the disclosed teaching without departing from the scope of the present invention. Therefore, the object of the present invention is not to define the specific embodiments that are disclosed as the preferred embodiments for carrying out the invention, and the disclosed device structure and the manufacturing method thereof will include all embodiments that fall within the scope of the present invention.

1. A thin film deposition method, comprising:
seasoning a first deposition chamber;
seasoning a second deposition chamber;
depositing a thin film in the first deposition chamber and cleaning the first deposition chamber; and
depositing a thin film in the second deposition chamber and cleaning the second deposition chamber;
characterized in that there is a time interval between the step of seasoning the second deposition chamber and the step of seasoning the first deposition chamber.

2. The thin film deposition method according to claim 1, wherein said time interval is a difference of a total time from transporting from a load-port to the end of deposition and cleaning between the first chamber and the second chamber.

3. The thin film deposition method according to claim 1, wherein said time interval may also be any other proper time interval selected according to specific process steps or execution processes of wafers, as long as the second deposition chamber does not have any idle time that affects thickness.

4. The thin film deposition method according to claim 1, wherein the first and/or second chamber are PECVD chambers.

5. The thin film deposition method according to claim 1, further comprising a step of seasoning a third deposition chamber, and the time interval between the step of seasoning the third deposition chamber and the step of seasoning the first deposition chamber is equal to or not equal to the time interval between the step of seasoning the second deposition chamber and the step of seasoning the first deposition chamber.

6. A method of manufacturing a semiconductor device, comprising:
depositing an etching barrier layer on a semiconductor structure;
depositing a dielectric insulating layer on the etching barrier layer using the thin film deposition method according to claim 1; and
depositing a cover layer on the dielectric insulating layer.

7. The method of manufacturing a semiconductor device according to claim 6, wherein the etching barrier layer includes SiN, NDC or N-Blok (Nitrogen Doped Carbide) or other dielectric materials that can be used for the barrier layer.

8. The method of manufacturing a semiconductor device according to claim 6, wherein the dielectric insulating layer includes a material of low dielectric constant.

9. The method of manufacturing a semiconductor device according to claim 8, wherein said material of low dielectric constant includes fluorosilicone glass (FSG), BD or SiOC (Carbon Doped Oxide) or other carbon-doped materials of low dielectric constant.

10. The method of manufacturing a semiconductor device according to claim 9, wherein said SiOC is made with OMCTS or TMCTS or other carbon-based precursors.

11. The method of manufacturing a semiconductor device according to claim 6, wherein the cover layer includes un-doped SiO₂ or doped SiO₂.

12. The method of manufacturing a semiconductor device according to claim 11, wherein the cover layer is made with TEOS, SiH₄ or precursors containing corresponding doping elements.

13. The method of manufacturing a semiconductor device according to claim 6, wherein the deposition is performed by using PECVD.

14. The method of manufacturing a semiconductor device according to claim 7, wherein the deposition is performed by using PECVD.

15. The method of manufacturing a semiconductor device according to claim 8, wherein the deposition is performed by using PECVD.

16. The method of manufacturing a semiconductor device according to claim 9, wherein the deposition is performed by using PECVD.

17. The method of manufacturing a semiconductor device according to claim 10, wherein the deposition is performed by using PECVD.

18. The method of manufacturing a semiconductor device according to claim 11, wherein the deposition is performed by using PECVD.

19. The method of manufacturing a semiconductor device according to claim 12, wherein the deposition is performed by using PECVD.
